(19) United States
(12) Patent Application Publication
(10) Pub. No.: US 2008/0095954 A1
(43) Pub. Date: Apr. 24, 2008

(54) Multilayer Coatings By Plasma Enhanced Chemical Vapor Deposition

(76) Inventors: Aaron M. Gabelnick, Ithaca, NY (US); Christina A. Lambert, Midland, MI (US)

Correspondence Address: The Dow Chemical Company, Intellectual Property Section, P.O. Box 1967, Midland, MI, 48641-1967, US

(21) Appl. No.: 11/661,055

(22) PCT Filed: Sep. 2, 2005
(86) PCT No.: PCT/US05/31456

§ 371 Date: Feb. 22, 2007

Related U.S. Application Data
(60) Provisional application No. 60/613,490, filed on Sep. 27, 2004.

(51) Int. Cl. C23C 16/513

(52) U.S. Cl. 427/579

(57) ABSTRACT

The present invention provides a process for preparing a multiple layer coating on the surface of an organic polymeric substrate by means of atmospheric pressure plasma deposition, the steps of the process comprising depositing a layer (first layer) of a plasma polymerized, optically clear, highly adherent, organosilicon compound onto the surface of the organic polymeric substrate by atmospheric pressure plasma deposition of a gaseous mixture comprising an organosilicon reagent compound and optionally an oxidant in a first step and thereafter in a second step depositing a substantially uniform layer (second layer) of a silicon oxide compound onto the exposed surface of said first layer by atmospheric pressure plasma deposition of a gaseous mixture comprising an oxidant and an organosilicon reagent compound, wherein the molar ratio of oxidant to organosilicon reagent compound in the gaseous mixture is greater in the second step than in the first step.

### BACKGROUND OF THE INVENTION

The present invention relates to coating or modifying a substrate using plasma enhanced chemical vapor deposition (PECVD), also referred to as glow discharge chemical vapor deposition, under atmospheric pressure or near atmospheric pressure conditions.

It is previously known to modify the surface of polymers such as polyolefins having an undesirably low surface energy in order to improve the surface wettability or adhesion or both, through deposition of a silicon oxide layer. Other polymers, such as polycarbonate have been similarly modified in order to provide improved chemical resistance, enhanced gas barrier, adhesion, antifog properties, abrasion resistance, static discharge, or altered refractive index.

U.S. Pat. No. 5,576,076 taught that the wettability and adhesion properties of polyolefin film can be improved by creating a deposit of a silicon oxide compound by subjecting the substrate to corona discharge at atmospheric pressure in the presence of a silane, a carrier gas, and an oxidant. U.S. Pat. No. 5,527,629 taught a similar process wherein oxygen in the form of residual air was present during the corona discharge treatment. Disadvantageously, the preferred silane in both processes, SiH₄, is readily oxidized, thereby requiring careful attention to prevent fires or the formation of silicon oxide particles.

U.S. Pat. No. 6,106,659 describes a cylinder-sleeve electrode assembly apparatus that generates plasma discharges in either an RF resonant excitation mode or a pulsed voltage excitation mode. The apparatus is operated at a rough vacuum with working gas pressures ranging from about 10 to about 760 Torr (1−100 kPa). Suitable compounds for use in the treatment included inert gases like argon, nitrogen and helium; oxidants such as oxygen, air, NO, N₂O, NO₂, N₂O₄, CO, CO₂ and SO₂; and treating compounds such as sulfur hexafluoride, tetrafluoromethane, hexafluoroethane, perfluoropropane, acrylic acid, silanes and substituted silanes, like dichlorosilane, silicon tetrachloride, and tetraethylorthosilicate.

U.S. Pat. No. 5,718,967 disclosed a process operating at reduced pressures for treating an organic polymer substrate such as polycarbonate to provide coatings by PECVD using one or more organosilicon compounds, including silanes, siloxanes and silazanes, especially tetramethyldisiloxane (TMDSO), and oxygen containing balance gases. Adhesion promoting layers formed by plasma polymerization of an organosilicon compound in the absence or substantial absence of oxygen are first prepared followed by a protective coating layer formed in the presence of a higher level of oxygen, preferably a stoichiometric excess of oxygen. Similar disclosures of processes and apparatus for use in these processes are contained in U.S. Pat. Nos. 5,298,587, 5,320,875 and 5,433,786.

In WO2003/066932, published Aug. 14, 2003, there was disclosed a corona discharge process for surface modification of a polymer substrate, especially polycarbonate or polypropylene, employing volatile silicone compounds. In Example 4, a two step deposition of an adhesive organosilicon layer using tetramethyldisiloxane (TMDSO), followed by deposition of a monolithic silicon oxide layer using tetraethylorthosilicate (TEOS) was disclosed. The oxidant employed in both steps was air.

### SUMMARY OF THE INVENTION

The present invention provides a process for preparing a multiple layer coating on the surface of an organic polymeric substrate by means of atmospheric pressure plasma deposition, the steps of the process comprising depositing a layer (first layer) of a plasma polymerized, optically clear, highly adherent, organosilicon compound onto the surface of the organic polymeric substrate by atmospheric pressure plasma deposition of a gaseous mixture comprising an organosilicon reagent compound and optionally an oxidant in a first step and thereafter in a second step depositing a substantially uniform layer (second layer) of a silicon oxide compound onto the exposed surface of said first layer by atmospheric pressure plasma deposition of a gaseous mixture comprising an oxidant and an organosilicon reagent compound, wherein the molar ratio of oxidant to organosilicon reagent compound in the gaseous mixture is greater in the second step than in the first step.

In a preferred embodiment, the present invention provides a process for preparing a multiple layer coating on the surface of an organic polymeric substrate by means of atmospheric pressure plasma deposition, the steps of the process comprising depositing a layer (first layer) of a plasma polymerized, optically clear, organosilicon compound of the formula SiN_{w}CₓO_{y}H_{z} onto the surface of the organic polymeric substrate by atmospheric pressure plasma deposition of a gaseous mixture comprising a organosilicon reagent and optionally an oxidant in a first step and thereafter in a second step depositing a substantially uniform layer (second layer) of a silicon oxide compound, preferably of the formula SiN_{w′}C_{x′}O_{y′}H_{z′} onto the exposed surface of said first layer by atmospheric pressure plasma deposition of a gaseous mixture comprising an oxidant and an organosilicon reagent, wherein:

w is a number from 0 to 1.0

x is a number from 0.1 to 3.0,

y is a number from 0.5 to 5.0,

z is a number from 0.1 to 5.0,

w′ is a number from 0 to 1.0,

x′ is a number from 0 to 0.5

y′ is a number from 1.0 to 5.0,

z′ is a number from 0.1 to 10.0, and

the molar ratio of oxidant to organosilicon reagent compound in the gaseous mixture in the second step is greater than in the first step.

Highly desirably the organosilicon reagent compound employed in both steps is the same. By using the same organosilicon reagent compound to produce all layers of a multiple layer film, the process can be greatly simplified, in as much as only one organosilicon reagent needs to be supplied to the apparatus. In addition, the deposition process may be conducted in a continuous manner by merely increasing the oxidant flow rate during the deposition process in order to discontinue forming the first layer and begin forming the second or subsequent layers. The process may also be operated in multiple steps or stages or in a manner to deposit the film over the entire exposed surface of the substrate such that either layer may be comprised of multiple sublayers or the chemical composition altered continuously or semi-continuously throughout the process to provide a gradient within each layer. In one such embodiment, the coating comprises a continuously varied composition comprising greater organic content and possessing increased flexibility at the surface in contact with the substrate and comprising reduced organic content and increased hardness at the exposed surface.

In a preferred embodiment, the first layer is a polymeric organosilicon compound that is more hydrophobic (oleophilic) than the succeeding layers and serves as an adhesive layer to more nearly match the surface properties of the organic polymer substrate, thereby resulting in improved adhesion of the multiple layer film. Moreover, the adhesive composition may include increased hydroxyl content as well as decreased crosslink density compared to prior art compositions. The resulting composition provides increased bonding strength to more polar organic polymers such as polycarbonate, acrylate or methacrylate based polymers and improved flexibility and elongation to the resulting multilayer coating. In addition, the silicon oxide layer, which is substantially lacking in organic moieties, and preferably is a monolithic siloxane or polymeric silicon oxide layer, has more hydrophilic properties, resulting in improved chemical resistance, decreased gas permeability, greater static dissipation, altered refractive index, and greater hardness, toughness and abrasion resistance.

### BRIEF DESCRIPTION OF DRAWINGS

FIG. 1 is an illustration of one apparatus used in the atmospheric pressure plasma deposition process.

FIG. 2 is an illustration of the side view of the electrode and counter-electrode.

FIG. 3 is an illustration of the electrode with slits as outlet ports.

FIG. 4 is an illustration of an arrangement and geometry of the electrode outlet ports.

FIG. 5 is a schematic drawing of another suitable arrangement of components in an apparatus for use in an atmospheric pressure plasma deposition process.

FIG. 6 is the FTIR absorption spectra of the coated substrates of Example 1.

### DETAILED DESCRIPTION OF THE INVENTION

For purposes of U.S. patent practice, the contents of any patent, patent application, or publication referenced herein are hereby incorporated by reference in their entirety (or the equivalent US version thereof is so incorporated by reference) especially with respect to the disclosure of synthetic techniques, raw materials, and general knowledge in the art. Unless stated to the contrary, implicit from the context, or customary in the art, all parts and percents are based on weight.

If appearing herein, the term “comprising” and derivatives thereof is not intended to exclude the presence of any additional component, step or procedure, whether or not the same is disclosed herein. In order to avoid any doubt, all compositions claimed herein through use of the term “comprising” may include any additional additive, adjuvant, or compound, unless stated to the contrary. In contrast, the term, “consisting essentially of” if appearing herein, excludes from the scope of any succeeding recitation any other component, step or procedure, excepting those that are not essential to operability. The term “consisting of”, if used, excludes any component, step or procedure not specifically delineated or listed. The term “or”, unless stated otherwise, refers to the listed members individually as well as in any combination.

As used herein the term “monolithic” refers to a solid layer substantially lacking in fissures, cracks and pits. Highly desirably, the solid lacks deformities extending greater than 10 percent of the thickness of the solid layer from the surface. The term “substantially uniform” refers to a solid layer having a mean thickness greater than or equal to 80 percent of the maximum thickness and lacking deformities extending greater than 25 percent of the thickness of the solid layer from the surface. The term “silicon oxide” refers to compounds containing at least some silicon oxygen bonds including polymeric silicon oxides containing less than a stoichiometric quantity of oxygen. The term “organosilicon compound” refers to compounds containing both silicon and one or more aliphatic, cycloaliphatic or aromatic groups bonded directly to the silicon or through one or more oxygen or nitrogen atoms. It is to be understood by the skilled artisan, that the formulas of the organosilicon and silicon oxide film compositions prepared herein are empirical formulas and not molecular formulas.

The term “highly adherent” or “adhesive layer” refers to a organosilicon film deposited onto an organic polymeric substrate, optionally in combination with a silicon oxide surface layer, which multilayer composition does not show loss of anticondensation properties, delamination or loss from the substrate surface when exposed to boiling water at a distance of 10 cm from the surface of the boiling water for at least three minutes, preferably at least 10 minutes. Highly desirably, the organic polymeric substrate comprises a polycarbonate, a polyolefin, or a poly(alkyl)acrylate polymer.

Any suitable apparatus for performing atmospheric pressure plasma deposition of the silicone compound can be employed in the present invention. Examples include those devices previously disclosed in U.S. Pat. No. 5,433,786, WO2003/066933, Ward et al., Langmuir, 2003 19, 2110-2114, and elsewhere. In all of the foregoing apparatuses, the organosilicon reagent compound is supplied as a vapor to a flowing stream of a gas (carrier gas) in the vicinity of an electrode, preferably by passing through or over the surface of the electrode, where a plasma is produced by electrical discharge between the electrode and a counter electrode. The amount of organosilicon reagent compound may be increased by use of heating to increase the vapor pressure thereof or by atomization using, for example, an ultrasonic atomizer. The latter method for achieving sufficient vapor pressure of the organosilicon reagent compound is preferred due to the avoidance of elevated temperatures that may approach the autoignition temperature of the gaseous mixture. Although the process is referred to as operating at atmospheric pressure, it is to be understood that pressures slightly above or below atmospheric (±20 kPa) are operable as well. Preferably the operating pressure is atmospheric or sufficiently above atmospheric pressure as needed to obtain the desired gas flow past the electrode(s).

Preferred organosilicon reagent compounds for use herein include compounds of the formula: R₄Si[OSi(R′)₂]ᵣ, wherein R and R′, independently each occurrence, are hydrogen, hydroxyl, C₁₋₁₀ hydrocarbyl, or C₁₋₁₀ hydrocarbyloxy, and r is a number from 0 to 10. Preferred organosilicon reagent compounds correspond to the formula: HₛSi(OR″)₄₋ₛ, or (R″)₃Si[OSi(OR″)₂]ₜOH, wherein R″, independently each occurrence is C₁₋₄ hydrocarbyl, preferably C₁₋₄ alkyl, most preferably methyl or ethyl, and s and t independently each occurrence are numbers from 0 to 4. Most highly preferred organosilicon reagent compounds are tetraC₁₋₄alkylorthosilicates, especially tetraethylorthosilicate.

Sufficient oxidant is provided in the form of a balance gas which may be mixed with the carrier gas prior to entry into the reactor or added separately to the reactor, to produce the desired product, that is, a polymeric organosilicon compound as the first layer, or by increasing the oxidant concentration, a polymeric siloxane or silicon oxide material as the second layer. Additional components of the gaseous mixture include inert substances such as nitrogen, helium, argon, or carbon dioxide. Suitable oxidants include O₂, O₃, NO, NO₂, N₂O, N₂O₃, and N₂O₄. The preferred oxidant is oxygen. A preferred gaseous mixture is air or a mixture of air or oxygen with nitrogen. In the first step, the quantity of oxidant present is more of less severely limited depending on the ease with which the organosilicon compound may be oxidized. Preferably, the quantity of oxidant in the working gas (carrier plus balance gas) is less than 1.0 mole percent, more preferably less than 0.1 mole percent and highly preferably less than 0.01 mole percent. Most desirably, the first step is conducted in the substantial absence of an oxidant. It is to be understood that adventitious quantities of oxygen will unavoidable be present in the reaction mixture due to infiltration from the surrounding atmosphere, impurities in the gases employed, or physi-sorbed on the substrate surface. Desirably, the quantity of organosilicon compound present in the gaseous mixture is maintained in the range from at least 50 ppm, preferably at least 200 ppm, and more preferably at least 500 ppm; and not greater than 10000 ppm, preferably not greater than 8000 ppm, and more preferably not greater than 7000 ppm. Reduced quantities of organosilicon compound in the reaction mixture result in reduced rates of coating deposition while elevated levels can result in gas phase nucleation which can cause poor film quality and even powder formation in the coating.

Highly desirably, the first layer contains residual organic and/or polar functionality such as hydroxyl or hydrocarbyloxy functionality. Desirably, such organic functionality, comprises from 0.1 to 10 mol percent of the adhesive polymer layer. The resulting product is also believed to be less highly cross-linked than a more fully oxidized layer, thereby imparting better flexibility to the coated layer. The first layer imparts improved adhesion properties in a multiple layer film construction. Moreover, the second layer, and to some extent the first layer, desirably comprise a small but less than stoichiometric quantity of nitrogen, for example, in the form of silicon nitride functional groups. Preferably, 0<w and w′<1.

In the process of the present invention, sufficient power density and frequency are applied to an electrode/counter electrode pair to create and maintain a glow discharge in a spacing between the electrode and counter electrode. The power density (based on electrode surface area exposed to the plasma) is preferably at least 1 W/cm², more preferably at least 5 W/cm², and most preferably at least 10 W/cm²; and preferably not greater than 200 W/cm², more preferably not greater than 100 W/cm², and most preferably not greater than 50 W/cm². The frequency is preferably at least 2 kHz, more preferably at least 5 kHz, and most preferably at least 10 kHz; and preferably not greater than 100 kHz, more preferably not greater than 60 kHz, and most preferably not greater than 40 kHz. The current applied to the electrodes may vary from 10 to 10,000 watts, preferably from 100 to 1000 watts, at potentials of 10 to 50,000 volts, preferably 100 to 20,000 volts.

The spacing between electrode and counter-electrode is sufficient to achieve and sustain a visible plasma (glow discharge), preferably at least 0.1 mm, more preferably at least 1 mm, and preferably not more than 50 mm, more preferably not more than 20 mm, and most preferably not more than 10 mm. The electrode, the counter electrode or both the electrode and the counter electrode may be fitted with a dielectric sleeve, if desired. In one embodiment, the electrode and counter electrode pair are encased within a high temperature resistant dielectric, such as a ceramic. The substrate to be coated may be supported or transported by the counter electrode or other wise supported in the vicinity of the plasma in order to be contacted or impinged by at least a portion of the plasma generated by the electrode and counter electrode. For the purposes of this invention, the terms electrode and counter electrode are used to refer to a first electrode and a second electrode, either of which can be polarized with the other being oppositely polarized or grounded. The flow of the carrier gas/balance gas together with the plasma generated in the vicinity of the electrodes causes plasma polymerized product to be deposited onto the surface of the substrate attached to the counter electrode or placed in the vicinity of an electrode pair. A suitable gap is provided between the substrate and the electrode or electrodes for exhaust of the carrier gas, by-products and unattached products. The width of the gap is adjusted to prevent incursion of excess amounts of contaminating gases, especially air.

Preferably the velocity of the total gas mixture through the electrode or electrode pair(s) is such that a stable plasma is formed allowing for uniform deposition of polymerized product. Desirably, the velocity of the gas passing through the exit ports is at least about 0.05 m/s, more preferably at least about 0.1 m/s, and most preferably at least about 0.2 m/s; and preferably not greater than about 1000 m/s, more preferably not greater than about 500 m/s, and most preferably not greater than about 200 m/s.

As defined herein “electrode” refers to a single conductive element or a plurality of conductive elements spaced sufficiently apart within a reactor equipped with sufficient gas flow to form a stable plasma when energized. Preferably, the electrode is hollow or equipped with a conduit for supply of the working gas mixture through one or more openings in the surface thereof. Thus, the term “past the electrode” refers to gas flowing through one or more inlets in the vicinity of the single element or multiple elements, past or near to a surface of the counter electrode, and past or onto the substrate to be coated through one or more outlets. Advantageously, because of the foregoing gas flow in an atmospheric pressure plasma deposition process, ablated material from the electrode or the walls of the reactor, if any, is substantially evacuated, thereby resulting in reduced surface defects and improved planarity in the resulting film.

Plasma polymerization as carried out by the process of the present invention typically results in an optically clear coating deposited on the surface of the substrate. The term “optically clear” is used herein to describe a coating having an optical clarity of at least 70 percent, more preferably at least 90 percent, and most preferably at least 98 percent and a haze value of preferably not greater than 10 percent, more preferably not greater than 2 percent, and most preferably not greater than 1 percent. Optical clarity is the ratio of transmitted-unscattered light to the sum of transmitted-unscattered and transmitted-scattered light (<2.5°). Haze is the ratio of transmitted-scattered light (>2.5°) to total transmitted light. These values are determined according to ASTM D 1003-97.

The substrate used in the present invention includes organic polymers in any form. Examples of substrates include sheets, fibers, and woven or non-woven fabrics of thermoplastics, such as polyolefins including polyethylene, polypropylene, and copolymerized mixtures of ethylene, propylene, and/or a C₄₋₈ α-olefin, polystyrenes, polycarbonates, polyesters including polyethylene terephthalate, polylactic acid, and polybutylene terephthalate, acrylates, methacrylates, and interpolymers of any of the monomers employed in the foregoing polymers A preferred substrate is polycarbonate sheet or film, that is, polycarbonate having a thickness from 0.001 to 10 cm. Highly desirably, the first layer (interchangeably herein referred to as an adhesive layer) is applied directly to the surface of the substrate to be coated, which may be washed or rinsed to remove foreign material but desirably without application of an intermediate layer such as a sputtered metal (metallization) and without treatment to alter surface properties such as use of corona discharge, uv-light, electron beam, ozone, oxygen, or other chemical or physical treatment to oxidize the surface in the absence of a silicon compound.

The invention is particularly adapted for use with substrates comprising homopolymers of an ester of (meth)acrylic acid, copolymers of more than one ester of (meth)acrylic acid, and copolymeric derivatives of the foregoing polymers additionally comprising one or more copolymerizable comonomers. Highly preferred esters of (meth)acrylic acid include the hydrocarbyl esters, especially alkyl esters, containing from 1 to 10 carbons, more preferably from 1 to 8 carbons in each ester group. Highly preferred esters include butylacrylate and methylmethacrylate. In addition, such polymers may include a copolymerizable comonomer, especially a divalent, cross-link forming comonomer (referred to as cross-linked, poly(meth)acrylate polymers). Examples especially include the di(meth)acrylate esters of dialcohols, especially alkylene glycols and poly(alkylene)glycols.

The foregoing crosslinked polymeric compositions preferably comprise hard segments or inhomogeneous regions, such as gels, formed by polymerization, including cross-link forming polymerizations, especially under biphasic polymerization conditions. One suitable example of such reaction conditions include polymerization by use of sequential, suspension or emulsion polymerization conditions to produce separate polymer segments having a difference in chemical or physical properties such that the resulting polymer lacks homogeneity. Such polymers are known in the art and commercially available. Examples include sequentially suspension polymerized cross-linked polymers of alkyl esters of acrylic and methacrylic acid. Such polymers can be produced by first reacting an alkyl ester of acrylic acid having an alkyl group containing 2 to 8 carbon atoms with 0.1 to 5 percent, preferably 0.5 to 1.5 percent, cross-linking monomer in an aqueous suspending medium. The cross-linking monomer is a bi- or polyfunctional compound with an ability to cross-link the alkyl acrylate. Suitable cross-linking monomers are alkylene glycol diacrylates such as ethylene glycol diacrylate and 1,3-butylene glycol diacrylate. In subsequent polymerization stages, increasing proportions of 1 to 4 carbon alkyl methacrylate are used, such that the resulting polymer contains inhomogeneous hard segmented regions. Suitable emulsifying agents and free radical initiators are used. Suitable polymers can also contain minor amounts of copolymerized acrylic and methacrylic acids. For example, a useful polymer can be a rubbery, cross-linked poly(alkyl acrylate) dispersed in a continuous phase of a predominantly methacrylate polymer, optionally containing minor amounts of acrylates, acrylic acid, or methacrylic acid copolymerized therewith. Such polymers are described further in U.S. Pat. Nos. 3,562,235, 3,812,205, 3,415,796, 3,654,069, and 3,473,99, and elsewhere.

The preferred polymer for use in at least the surface layer of a substrate herein is a crosslinked poly(meth)acrylate polymer, designated by the trademark KORAD™, and sold by Spartech PEP or SOLARCOA™, sold by Atoglass, Inc. In a particularly preferred embodiment, a polymer layer of such product in the form of a film is laminated to a polycarbonate sheet or film, or to a sheet or film layer of a poly(meth)acrylate polymer, which in turn may be laminated to a further polymer sheet or film layer, especially a polycarbonate layer. The resulting two or three layer construct is particularly desired for use as a plastic glazing material, especially where a UV absorbing material, such as an organic benzotriazole such as TINUVIN, available from Ciba, an organotin compound, zinc oxide, or similar material is incorporated into the surface layer. A structure in which the foregoing glazing material is constructed with the W absorbing layer, especially an all (meth)acrylate polymer comprising from 0.01 to 10 percent UV absorbing material, especially an organic benzotriazole, exposed to the atmosphere or other source of UV radiation, possesses improved degradation resistance under exposure conditions, while the present abrasion resistant layer provides improved crazing, abrasion, and mar resistance. Suitable methods for forming polymeric laminates for use herein include use of an adhesive such as a cyanurate compound, a low molecular weight polybutylacrylate, or any other suitable adhesive to join the respective layers. Melt lamination of the respective polymers may be employed as well.

In one unique embodiment of the invention, the substrate comprises a laminate of one or more poly(meth)acrylate polymer layers and one or more polycarbonate homopolymers or copolymer layers in a thickness providing impact resistance. In particular, such structures are sufficiently impact resistant to provide ballistic impact resistance and are known for use in bullet resistant glazing applications. In a unique application, a two layered version of the foregoing poly(meth)acrylate/polycarbonate structure is known to resist penetration from projectiles impinging on the poly(meth)acrylate side of the laminate, but are readily penetrated by projectiles impinging on the polycarbonate side thereof. Accordingly, a structure, such as an automobile, equipped with such laminated glazing, oriented with the poly(meth)acrylate layer facing the outside, possesses enhanced protection from bullets or projectiles originating outside the automobile, while allowing return fire originating inside the vehicle to be used to defend in case of attack (one-way bullet resistance). Application of the abrasion resistant coating of the present invention to exterior surface of such a structure, optionally over a film of a cross-linked poly(meth)acrylate polymer, especially KORAD™, imparts improved abrasion resistance to such glazing material without sacrifice of ballistic impact resistance, especially one-way bullet impact resistance. Additionally, inclusion of a UV protective layer or component, desirably by incorporation in the cross-linked poly(meth)acrylate polymer layer or the poly(meth)acrylate polymer layer, imparts added lifetime and degradation resistance to the resulting structure under exposure to UV light.

The abrasion resistant coating of the invention is applied to a film or sheet of the polymeric substrate before or after formation of a laminate with other polymeric materials. In a preferred embodiment, the abrasion resistant coating is applied as a final step in a cast or extrusion, sheet or film forming process. The coated product may be thereafter cut to size, formed into desired shapes, or laminated to solid materials or substances without loss or degradation of the abrasion resistant coating.

The process equipment may be located in an inert environment, but preferably is operated under ambient atmospheric conditions. The process is operated at atmospheric pressure with sufficient volumetric flow of working gas or the use of seals, vacuum ports or other suitable means to reduce incursion of ambient gases leading to alteration of the working gas composition. Preferably, the volumetric flow of working gas (including organosilicon compound, carrier gas, oxidant and balance gas) is from 10 to 1,500 cc/minute per cm² of electrode surface.

Any suitable electrode geometry and reactor design can be employed in the present process. For thick substrates, such as sheet material, it may be desirable that both the electrode and the counter electrode be located on the same side of the substrate to be coated. Plasma created reaction products are impinged onto the surface of the substrate after passing by the electrodes. Exhaust ports from the reactor are located near the substrate surface and spatially removed from the electrodes to permit contact of the plasma or at least the reaction products formed therein with the substrate surface before exiting the reactor. If desired, the shape of the resulting corona discharge may be modified by the use of a magnetic field as previously disclosed in the art. For thinner substrates, the counter electrode may be a conductive surface upon which the target or substrate is supported. Either the substrate or the entire counter electrode containing the substrate may be moving, especially in a continuous treating process.

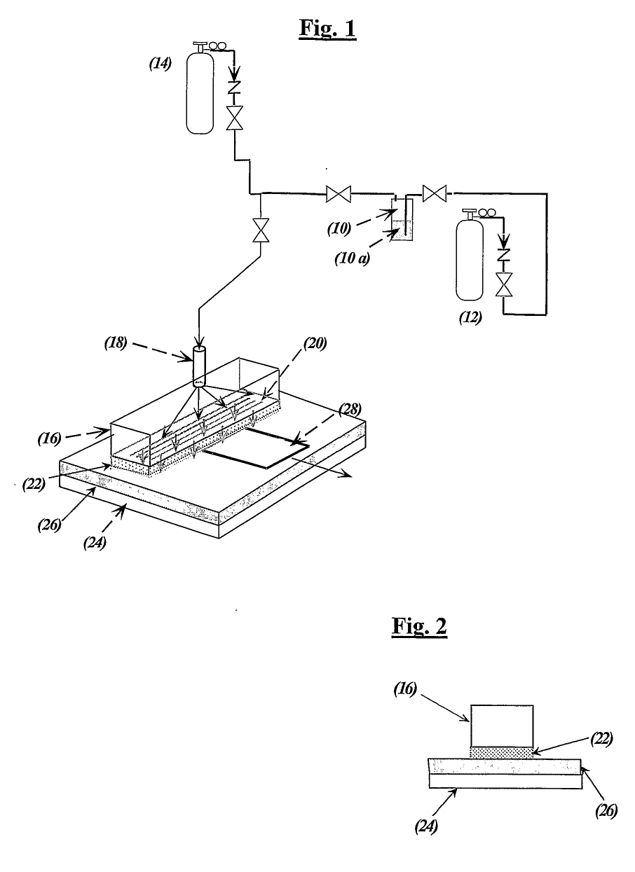

FIG. 1 provides an illustration of one apparatus used in carrying out the method of the present invention with a flexible film substrate. In FIG. 1, organosilicon compound (10) is generated from the headspace of a contained volatile liquid (10a) of the organosilicon compound, carried by a carrier gas (12) from the headspace and merged with balance gas (14) before transport to the electrode (16). The carrier gas (12) and the balance gas (14) drive the organosilicon compound (10) through the electrode (16), more particularly, through at least one inlet (18) of electrode (16), and through outlets (20), which are typically in the form of slits or holes or the gaps between a plurality of conductive elements. Power is applied to the electrode (16) to create a glow discharge (22) between the electrode (16) and the counter-electrode (24), which is optionally fitted with a dielectric layer (26). It is to be understood that the electrode (16) may also or alternatively be fitted with a dielectric sleeve (not shown in the figure). Substrate (28) is passed continuously along the dielectric layer (26) and coated with the polymeric silicon oxide product in the form of a monolithic film.

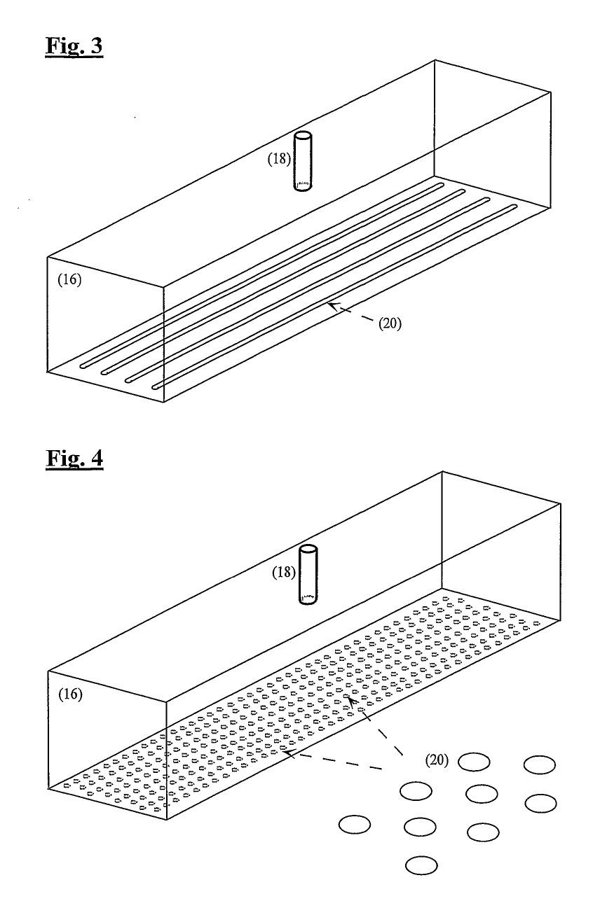

FIG. 2 is a side view illustration of electrode (16), counter-electrode (24), dielectric (26) and glow discharge region (22). Where the substrate is nonconductive, the dielectric layer (26) may be omitted.

FIG. 3 is an illustration of a preferred embodiment of the electrode outlets (20), which are in the form of parallel or substantially parallel, substantially evenly spaced slits that extend approximately the length of the electrode. The width of the slits is preferably not less than 0.1 mm, more preferably not less than 0.2 mm, and most preferably not less than 0.5 mm; and preferably not more than 10 mm, more preferably not more than 5 mm, and most preferably not more than 2 mm.

FIG. 4 is an illustration of another preferred geometry and spacing of the electrode outlets (20), which are in the form of substantially circular orifices. If this geometry is used to practice the method of the present invention, the diameter of the outlets is not less than 0.05 mm, more preferably not less than 0.1 mm, and most preferably not less than 0.2 mm; and preferably not greater than 10 mm, more preferably not greater than 5 mm, and most preferably not greater than 1 mm.

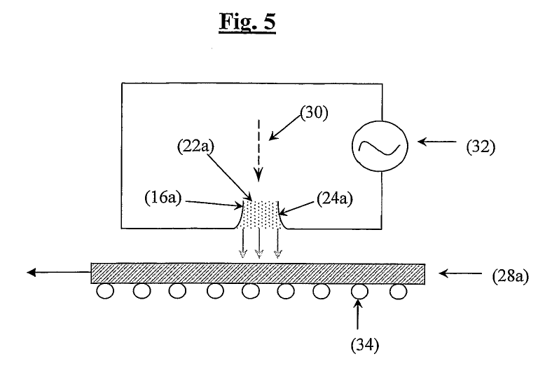

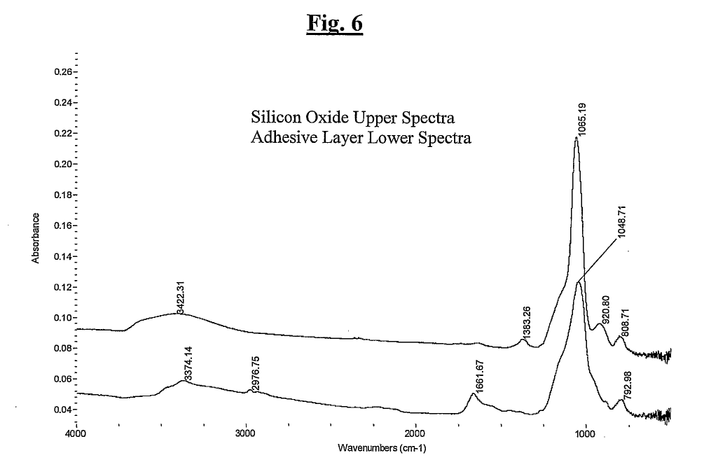

FIG. 5 is a schematic illustration of an atmospheric pressure plasma deposition process including supply means for tetraalkylsiloxane (30), a power supply (32) connected to stationary electrode (16a) and counter electrode (24a) between which a plasma (22a) is generated. The substrate (28a) is supported by a transport mechanism such as rollers (34) and passes through at least a portion of the plasma (22a).

It has been surprisingly discovered that a multiple layer coating comprising first a monolithic, optically clear adhesion layer of a polymeric organosilicon material on the substrate surface and second a monolithic, optically clear, contiguous silicon oxide coating that is powder-free or substantially powder-free, can be rapidly deposited on a substrate using the multiple step process of the invention employing the same organosilicon compound as a reagent in both steps.

The following specific embodiments of the invention are especially desirable and hereby delineated in order to provide a detailed disclosure for the appended claims.

1. A process for preparing a multiple layer coating on the surface of an organic polymeric substrate by means of atmospheric pressure plasma deposition, the steps of the process comprising depositing a layer (first layer) of a plasma polymerized, optically clear, highly adherent, organosilicon compound onto the surface of the organic polymeric substrate by atmospheric pressure plasma deposition of a gaseous mixture comprising a tetraalkylorthosilicate compound and optionally an oxidant in a first step and thereafter in a second step depositing a substantially uniform layer (second layer) of a silicon oxide compound onto the exposed surface of said first layer by atmospheric pressure plasma deposition of a gaseous mixture comprising an oxidant and a tetraalkylorthosilicate compound, wherein the molar ratio of oxidant to tetraalkylorthosilicate compound in the gaseous mixture used is greater in the second step than in the first step.

2. The process of claim 1 wherein the organosilicon compound used in the first and second steps is a tetraalkylorthosilicate.

3. The process of claim 2 wherein the tetraalkylorthosilicate is tetraethylorthosilicate.

4. The process of claim 1 wherein the surface of the substrate is not pretreated by metallization or by chemical or physical oxidation processes in the absence of a silicon compound.

5. The process of any one of claims 1-4 wherein the organic polymer substrate is a polycarbonate.

6. The process of claim 5 wherein the oxidant is O₂.

7. A process for preparing a multiple layer coating on the surface of an organic polymeric substrate by means of atmospheric pressure plasma deposition, the steps of the process comprising depositing a layer (first layer) of a plasma polymerized, optically clear, organosilicon compound of the formula SiN_{w}CₓO_{y}H_{z} onto the surface of the organic polymeric substrate by atmospheric pressure plasma deposition of a gaseous mixture comprising a tetraalkylorthosilicate compound and optionally an oxidant in a first step and thereafter in a second step depositing a substantially uniform layer (second layer) of a silicon oxide compound onto the exposed surface of said first layer by atmospheric pressure plasma deposition of a gaseous mixture comprising an oxidant and a tetraalkylorthosilicate compound, wherein the molar ratio of oxidant to tetraalkylorthosilicate compound in the gaseous mixture used in the second step is greater than in the first step.

8. The process of claim 7 wherein the silicon oxide compound corresponds to the formula: SiN_{w′}C_{x′}O_{y′}H_{z′}, wherein:

w is a number from 0 to 1.0

x is a number from 0.1 to 3.0,

y is a number from 0.5 to 5.0,

z is a number from 0.1 to 5.0,

w′ is a number from 0 to 1.0,

x′ is a number from 0 to 0.5

y′ is a number from 1.0 to 5.0, and

z′ is a number from 0.1 to 10.0.

9. The process of claim 7 wherein the tetraalkylorthosilicate compound used in the first and second steps is the same.

10. The process of claim 9 wherein the tetraalkylorthosilicate compound is tetraethylorthosilicate.

11. The process of claim 7 wherein the surface of the substrate is not pretreated by metallization or by chemical or physical oxidation processes.

12. The process of any one of claims 7 to 11 wherein the organic polymer substrate is a polycarbonate.

13. The process of any one of claims 7 to 11 wherein the organic polymer substrate is a poly(meth)acrylate.

4. The process of claim 12 or 13 wherein the oxidant is O₂.

### EXAMPLES

The invention is further illustrated by the following examples that should not be regarded as limiting of the present invention. Unless stated to the contrary or conventional in the art, all parts and percents are based on weight.

### Example 1

### Polycarbonate Substrate with Hydrophobic/Hydrophilic Coating

A polycarbonate substrate is coated with a polymeric organosilicon film using the apparatus substantially as illustrated in FIG. 5. The electrodes and power supply are obtained from Corotec Industries, Farmington, Conn. The equipment is designed with a gas inlet above the discharge region which injects the working gas into a space between a vertically disposed electrode and counter electrode 10 cm in length located above a discharge zone at a pressure slightly above atmospheric (1.02 kPa). The power supply is adjusted to 12 kV and 0.060 A to provide a non-thermal arc discharge. The substrate is supported on rollers and is passed beneath the discharge zone at a uniform rate. The entire apparatus is located in a normal atmospheric environment.

The substrate having a thickness of 10 mil (0.25 mm) is washed with methanol to remove surface contaminants but otherwise untreated. Tetraethylorthosilicate (TEOS) is heated to 120° C. and mixed with nitrogen carrier gas at 20° C. to provide a concentration of 24 percent v/v TEOS/N₂. The adjusted flow rate of the TEOS/N₂ mixture is 2000 standard cm³/min (sccm) and the flow rate of the balance gas (also N₂) is 25 standard ft³/min (scfm) (710,000 sccm) giving a concentration of TEOS based on the total gas mixture of 680 ppm. The overall gas velocity to the substrate is 8 m/s. The substrate is coated twice at a line speed of 2 m/min to provide an organosilicon coating of approximately 10 nm thickness. The resultant coating is analyzed by FTIR and XPS. The approximate chemical composition is determined to be SiO_{3.3}C_{1.8} H_{z}N_{0.3}, where z is greater than 0.1 and less than 4. The surface contact angle as measured by an optical goniometer using 100 μl water droplets is 50° compared to 63° for the untreated polycarbonate surface.

The preceding process is substantially repeated to prepare an adhesive layer (first layer) followed immediately by deposition of a silicon oxide layer prepared by substituting air as the balance gas at a flow rate of 25 standard ft³/min (scfm) (710,000 sccm) with all other conditions remaining the same to provide a dual layer coating. Two passes are employed to build each layer resulting in a total thickness to approximately 20 nm. The resultant coating is analyzed by FTIR. The approximate chemical formula of the surface layer is determined to be SiO_{1.9}H_{z}, where z is greater than 0 and less than 1. Contact angle measurements of the surface layer are repeated giving a value of 5°. The extremely small contact angle measurement indicates the surface is more hydrophilic than the original polycarbonate surface or the adhesive layer surface.

The resulting two-layer coated polycarbonate sheet is tested for adhesion of the dual component surface layer. Samples are tested by placing plaques approximately 10 cm above the surface of boiling water for varying time periods. Poor adhesion is evidenced by diminution of the anticondensation properties of the sample as measured by optical transmission (ASTM D 1003-97). Samples according to the Example retain anticondensation properties indefinitely. Samples prepared without the adhesion layer (only the second layer) with or without initial surface treatment by corona discharge only and with conditions for applying the silicon oxide layer otherwise substantially according to the Example show diminution of anticondensation properties after three minutes exposure to boiling water.

The surfaces (adhesive coating only and two layer coating) are also analyzed by Fourier Transform Infrared Spectroscopy. Results are depicted in FIG. 6. The presence of peaks at an absorption maximum of 2977 cm⁻¹ and 1662 cm⁻¹, believed to be attributable to ethoxy and nitrogen polar functionality respectively in the adhesive layer, are not detectable in the silicon oxide layer.

1. A process for preparing a multiple layer coating on the surface of an organic polymeric substrate by means of atmospheric pressure plasma deposition, the steps of the process comprising depositing a layer (first layer) of a plasma polymerized, optically clear, highly adherent, organosilicon compound onto the surface of the organic polymeric substrate by atmospheric pressure plasma deposition of a gaseous mixture comprising a tetraalkylorthosilicate compound and optionally an oxidant in a first step and thereafter in a second step depositing a substantially uniform layer (second layer) of a silicon oxide compound onto the exposed surface of said first layer by atmospheric pressure plasma deposition of a gaseous mixture comprising an oxidant and a tetraalkylorthosilicate compound, wherein the molar ratio of oxidant to tetraalkylorthosilicate compound in the gaseous mixture used is greater in the second step than in the first step.

2. The process of claim 1 wherein the organosilicon compound used in the first and second steps is a tetraalkylorthosilicate.

3. The process of claim 2 wherein the tetraalkylorthosilicate is tetraethylorthosilicate.

4. The process of claim 1 wherein the surface of the substrate is not pretreated by metallization or by chemical or physical oxidation processes in the absence of a silicon compound.

5. The process of any one of claims 1-4 wherein the organic polymer substrate is a polycarbonate.

6. The process of claim 5 wherein the oxidant is O₂.

7. A process for preparing a multiple layer coating on the surface of an organic polymeric substrate by means of atmospheric pressure plasma deposition, the steps of the process comprising depositing a layer (first layer) of a plasma polymerized, optically clear, organosilicon compound of the formula SiN_{w}CₓO_{y}H_{z} onto the surface of the organic polymeric substrate by atmospheric pressure plasma deposition of a gaseous mixture comprising a tetraalkylorthosilicate compound and optionally an oxidant in a first step and thereafter in a second step depositing a substantially uniform layer (second layer) of a silicon oxide compound onto the exposed surface of said first layer by atmospheric pressure plasma deposition of a gaseous mixture comprising an oxidant and a tetraalkylorthosilicate compound, wherein the molar ratio of oxidant to tetraalkylorthosilicate compound in the gaseous mixture used in the second step is greater than in the first step.

8. The process of claim 7 wherein the silicon oxide compound corresponds to the formula: SiN_{w′}C_{x′}O_{y′}H_{z′}, wherein:
w is a number from 0 to 1.0
x is a number from 0.1 to 3.0,
y is a number from 0.5 to 5.0,
z is a number from 0.1 to 5.0,
w′ is a number from 0 to 1.0,
x′ is a number from 0 to 0.5
y′ is a number from 1.0 to 5.0, and
z′ is a number from 0.1 to 10.0.

9. The process of claim 7 wherein the tetraalkylorthosilicate compound used in the first and second steps is the same.

10. The process of claim 9 wherein the tetraalkylorthosilicate compound is tetraethylorthosilicate.

11. The process of claim 7 wherein the surface of the substrate is not pretreated by metallization or by chemical or physical oxidation processes.

12. The process of any one of claims 7 to 11 wherein the organic polymer substrate is a polycarbonate.

13. The process of any one of claims 7 to 11 wherein the organic polymer substrate is a poly(meth)acrylate.

14. The process of claim 12 or 13 wherein the oxidant is O₂.
